(19) United States
(12) Patent Application Publication
(10) Pub. No.: US 2025/0293093 A1
(43) Pub. Date: Sep. 18, 2025

(54) METHOD OF MANUFACTURING SEMICONDUCTOR DEVICE

(71) Applicant: SK hynix Inc., Gyeonggi-do (KR)

(72) Inventor: Jong Su KIM, Gyeonggi-do (KR)

(21) Appl. No.: 18/788,161

(22) Filed: Jul. 30, 2024

(30) Foreign Application Priority Data
Mar. 12, 2024 (KR) 10-2024-0034632

(51) Int. Cl. H01L 21/78; H01L 21/02; H01L 21/304

(52) U.S. Cl. CPC H01L 21/78; H01L 21/02013; H01L 21/02016; H01L 21/304

(57) ABSTRACT

In a method of manufacturing a semiconductor device, a bulk substrate includes a plurality of semiconductor chip regions and a scribe lane region between the semiconductor chip regions. A lower dicing inducer having a first depth is formed in the scribe lane region of the bulk substrate. A dummy layer is formed on the scribe lane region of the bulk substrate. The dummy layer includes at least one upper dicing inducer. A passivation layer is formed on the dummy layer. The passivation layer is etched to form a recess in the passivation layer. A backside of the bulk substrate is grinded to generate cracks along at least one of a boundary of the lower dicing inducer, a boundary of the upper dicing inducer, a boundary between the bulk substrate and the dummy layer and a boundary of the recess. The semiconductor chip regions are singulated by the cracks.

### CROSS-REFERENCES TO RELATED APPLICATION

The present application claims priority under 35 U.S.C. § 119(a) to Korean patent application number 10-2024-0034632, filed on Mar. 12, 2024, which is incorporated herein by reference in its entirety.

### BACKGROUND

### 1. Technical Field

Various embodiments of the present disclosure generally relate to a semiconductor device and a method of manufacturing the same, more particularly, to a semiconductor device including a dicing inducer and a method of manufacturing the semiconductor device.

### 2. Related Art

A wafer may include a plurality of semiconductor chips divided by a scribe lane. Each of the semiconductor chips may include semiconductor devices having various functions.

A wafer dicing process may include cutting the wafer along the scribe lane to singulate the semiconductor chips. The wafer dicing process may use a blade, a laser, etc.

Recently, the laser rather than the blade, which may have a large substrate consumption compared to the laser, may be mainly used for the wafer dicing process.

As the semiconductor device may have been highly integrated, an area of the scribe lane as well as an area of the semiconductor chip may have been downscaled. However, when the wafer is cut using the laser, it is generally difficult to decrease the area of the scribe lane due to a wavelength of the laser beam and a margin of the laser beam.

### SUMMARY

Various embodiments of the present disclosure provide a semiconductor device that may be capable of securing an area of a semiconductor chip.

Various embodiments of the present disclosure also provide a method of manufacturing the above-mentioned semiconductor device.

According to an embodiment of the present disclosure a method of manufacturing a semiconductor device is provided, the method comprising preparing a bulk substrate. The bulk substrate may include a plurality of semiconductor chip regions and a scribe lane region between the semiconductor chip regions. A lower dicing inducer having a first depth may be formed in the scribe lane region of the bulk substrate. A dummy layer may be formed on the scribe lane region of the bulk substrate. The dummy layer may include at least one upper dicing inducer. A passivation layer may be formed on the dummy layer. The passivation layer may be etched to form a recess in the passivation layer. A backside of the bulk substrate may be grinded to generate cracks along at least one of a boundary of the lower dicing inducer, a boundary of the upper dicing inducer, a boundary between the bulk substrate and the dummy layer and a boundary of the recess, thereby singulating the plurality of the semiconductor chip regions by the cracks.

According to another embodiment of the present disclosure, a semiconductor device is provided, the semiconductor device comprising a substrate, a lower dicing inducer, a dummy layer and an upper dicing inducer. The substrate may include a plurality of semiconductor chip regions and a scribe lane region between the semiconductor chip regions. The lower dicing inducer may be formed through the scribe lane region of the substrate. The dummy layer may be formed on the scribe lane region. The upper dicing inducer may be positioned adjacent to the lower dicing inducer. The upper dicing inducer may be formed through the dummy layer.

In some embodiments, the dummy layer may include a plurality of insulating interlayers. The upper dicing inducer may include a vertical connection and a horizontal connection. The vertical connection may be formed in each of the insulating interlayers. The horizontal connection may be arranged between the adjacent insulating interlayers. The horizontal connection may be connected to the vertical connection.

In some embodiments, each of the semiconductor chip regions may include a cell region and an edge region. The insulating interlayers may be formed on the edge region. At least one guard ring may be formed in the insulating interlayers. The guard ring may have a shape substantially the same as a shape of the upper dicing inducer.

In some embodiments, the upper dicing inducer may include a first upper dicing inducer and a second upper dicing inducer. The first upper dicing inducer may be arranged at a central portion of the lower dicing inducer. The second upper dicing inducer may be arranged on at least one of a first sidewall and a second sidewall of the lower dicing inducer.

In some embodiments, the lower dicing inducer and the upper dicing inducer may be continuously or discontinuously arranged along the scribe lane region on a planar view.

According to an embodiment, of the present disclosure, a semiconductor device may include a substrate and a semiconductor chip. The semiconductor chip may include a device layer on the substrate. At least one edge portion of the semiconductor chip may include at least one upper dicing inducer positioned outside the device layer. The at least one edge portion of the semiconductor chip may further include a lower dicing inducer formed through the substrate.

According to some embodiments of the present disclosure, a wafer may be cut using the cracks generated in the dicing inducer without a laser or a blade. Thus, a width of the scribe lane region may be decreased to a width of the dicing inducer. As a result, the decreased width of the scribe lane region may be used for a width of the semiconductor chip to secure an area of the semiconductor chip.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIGS. 1A and 1B are plan views illustrating a semiconductor device in accordance with embodiments of the present disclosure;

FIG. 2 is a cross-sectional view illustrating a portion “A” in FIG. 1A or 1B;

FIG. 3 is a flow chart illustrating a method of manufacturing a semiconductor device in accordance with embodiments of the present disclosure;

FIGS. 4A to 8A are plan views illustrating a method of manufacturing a semiconductor device in accordance with embodiments of the present disclosure;

FIGS. 4B to 8B are cross-sectional views illustrating a method of manufacturing a semiconductor device in accordance with embodiments of the present disclosure;

FIGS. 9A and 9B are cross-sectional views illustrating a method of manufacturing a semiconductor device in accordance with embodiments of the present disclosure;

FIG. 10 is a cross-sectional view illustrating a semiconductor chip in accordance with embodiments of the present disclosure; and

FIG. 11 is a cross-sectional view illustrating a method of manufacturing a semiconductor device in accordance with embodiments of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the embodiments of the present disclosure as defined in the appended claims.

The present invention is described herein with reference to cross-section and/or plan illustrations of embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

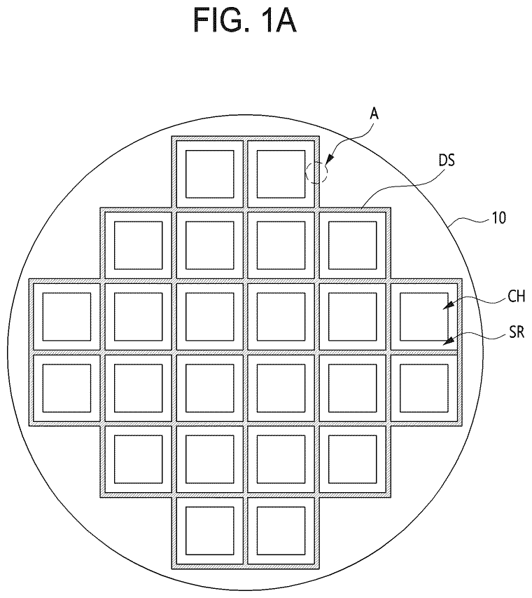

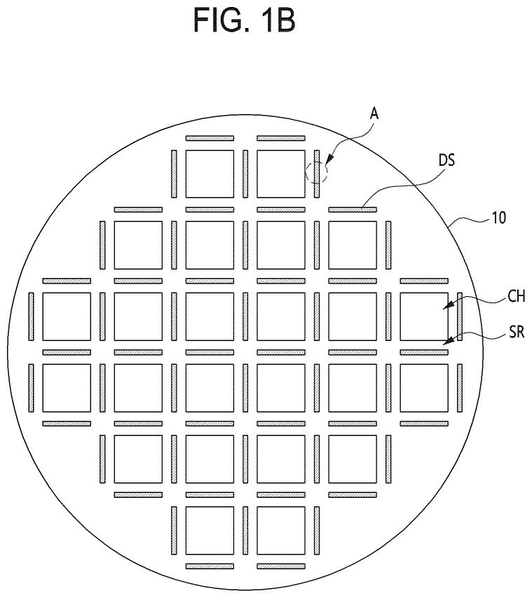

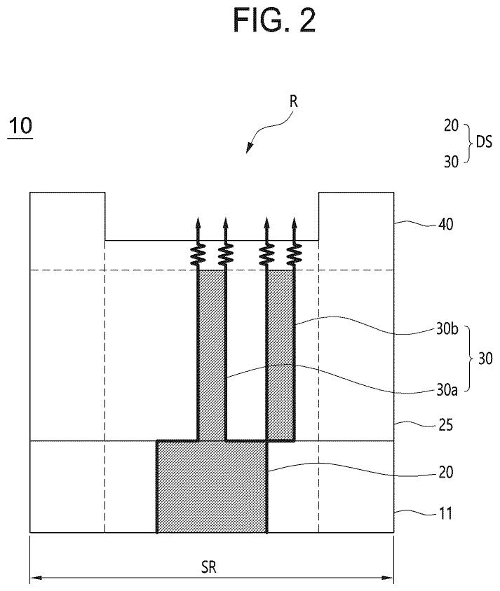

FIGS. 1A and 1B are plan views illustrating a semiconductor device in accordance with embodiments of the present disclosure and FIG. 2 is a cross-sectional view illustrating a portion “A” in FIG. 1A or 1B.

Referring to FIGS. 1A, 1B and 2, a wafer 10 of some embodiments may include a plurality of semiconductor chip regions CH, a scribe lane region SR and at least one dicing inducer DS.

A plurality of semiconductor devices having various functions may be integrated in the semiconductor chip regions CH.

The scribe lane region SR may be configured to define the semiconductor chip regions CH. The scribe lane region SR may be cut by various dicing manners. The scribe lane region SR may be a preliminary region including an actual cutting region.

The dicing inducer DS may be positioned in the scribe lane region SR. The dicing inducer DS may induce cracks in various directions, for example, a thickness direction of the wafer represented by an arrow in FIG. 2.

In some embodiments, the dicing inducer DS may be formed at the scribe lane region SR. On a planar view, as shown in FIG. 1A, the dicing inducer DS may be continuously arranged in the scribe lane region SR. Alternatively, as shown in FIG. 1B, the dicing inducer DS may be discontinuously arranged in the scribe lane region SR.

For example, the wafer 10 may include a semiconductor substrate 11. A dummy layer 25 may be formed over the semiconductor substrate 11 of the scribe lane region SR.

The dicing inducer DS may include a lower dicing inducer 20 and an upper dicing inducer 30. The lower dicing inducer 20 may be formed in the semiconductor substrate 11. For example, the lower dicing inducer 20 may be formed to pass through the semiconductor substrate 11. As shown in FIG. 2 the lower dicing inducer 20 may have lowermost and uppermost surfaces that are coplanar with the lowermost and uppermost surfaces of the semiconductor substrate 11, respectively. The lower dicing inducer 20 may induce the cracks from a lowermost surface of the semiconductor substrate 11 to an uppermost surface of the semiconductor substrate 11. The upper dicing inducer 30 may be arranged over the lower dicing inducer 20. For example, the upper dicing inducer 30 may be formed to pass through the dummy layer 25. For example, the upper dicing inducer 30 may include a first upper dicing inducer 30a and a second upper dicing inducer 30b. The first upper dicing inducer 30a may be positioned at a central portion of the lower dicing inducer 20. The second upper dicing inducer 30b may be positioned at an edge portion of the lower dicing inducer 20. The upper dicing inducer 30 may transfer the cracks progressed from the lower dicing inducer 20 to an uppermost surface of the dummy layer 25 from a lowermost surface of the dummy layer 25 along a vertical direction, i.e., a thickness direction of the dummy layer 25. In FIG. 2, the first upper dicing inducer 30a and the second upper dicing inducer 30b may each have a plug structure or plug shape formed to extend through the dummy layer 25. Alternatively, the first upper dicing inducer 30a and the second upper dicing inducer 30b may include a multiple plug in accordance with a structure of the dummy layer 25.

A plurality of circuit elements for forming the semiconductor device may be formed in/over the semiconductor substrate 11 of the semiconductor chip regions CH.

A passivation layer 40 may be formed over the dummy layer 25 of the scribe lane region SR and the semiconductor chip regions CH. A recess R may be formed in the passivation layer 40 formed at the scribe lane region SR. A depth of the recess R may be less than a thickness of the passivation layer 40. Thus, the passivation layer 40 having a set thickness may remain between a bottom surface of the recess R and the uppermost surface of the upper dicing inducer 30. The set thickness may allow the cracks generated by a momentum of the cracks to spread in the vertical direction due to the lower dicing inducer 20, the upper dicing inducer 30, a stress generated in forming the recess R, and stress processes that may subsequently generate, such as a back grinding process. The set thickness may be determined based on the thicknesses of the lower dicing inducer 20 and the upper dicing inducer 30.

The lower dicing inducer 20 and the upper dicing inducer 30 may be positioned under the bottom surface of the recess R and within the perimeter of the recess R. Thus, the wafer 10 may be cut (or diced) within a width of the recess R.

In some embodiments, the width of the recess R may be wider than a width of the lower dicing inducer 20. The width of the recess R may be narrower than the width of the scribe lane region SR. An actual cut width of the wafer may be wider than the width of the lower dicing inducer 20. The actual cut width of the wafer may be narrower than the width of the recess R.

Although not depicted in the drawings, test patterns, alignment patterns, vernier patterns, dummy patterns, etc., in the scribe lane region SR may be formed in the dummy layer 25.

For example, when the semiconductor substrate 11 may include silicon, the semiconductor substrate 11 may have a silicon atomic bonding. In contrast, because the semiconductor substrate 11 and the lower dicing inducer 20 may include different materials and the upper and lower dicing inducers 30 and 20 may also include different materials, heterojunctions may form at the boundary between the semiconductor substrate 11 and the lower dicing inducer 20 and at the boundary between the upper dicing inducer 30 and the dummy layer 25. The heterojunctions may have a weaker bonding strength (or junction strength) than the bonding strength of a single bond. Thus, when a stimulus is applied to the boundary of each heterojunction, the cracks may easily generate at the boundaries. Particularly, because the etching process for forming a trench/hole may be performed on the lower dicing inducer 20 and the upper dicing inducer 30, defects caused by the etching process may be generated in the heterojunction boundaries. The defects may weaken the bonding strength of the heterojunction.

Therefore, when a process such as a grinding process is performed on the semiconductor substrate 11 for applying a high stress to the semiconductor substrate 11, the heterojunctions of the boundaries may be continuously broken to form the cracks.

The cracks may continuously promulgate or progress to the bottom surface of the recess R along the sidewalls of the lower dicing inducer 20 and the upper dicing inducer 30. As a result, the wafer may be more easily cut without a laser.

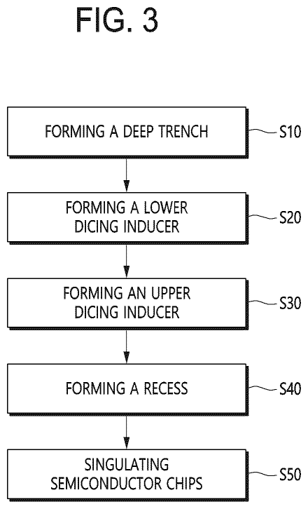

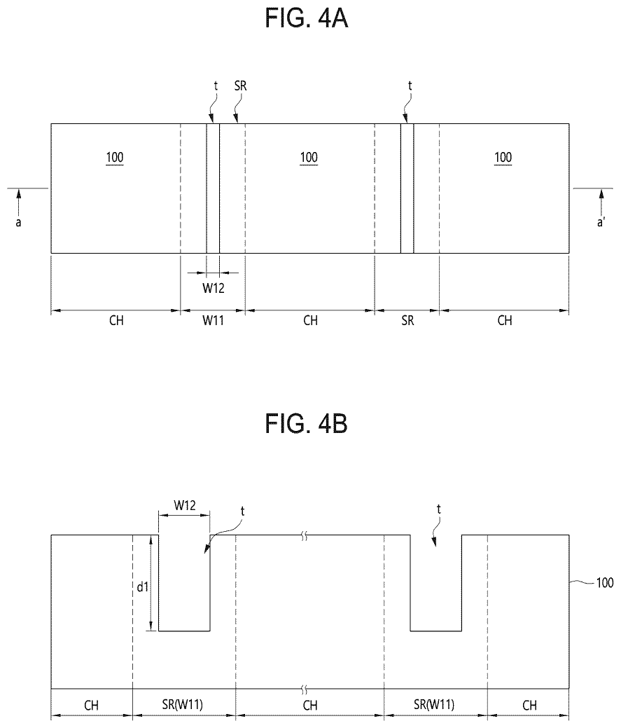

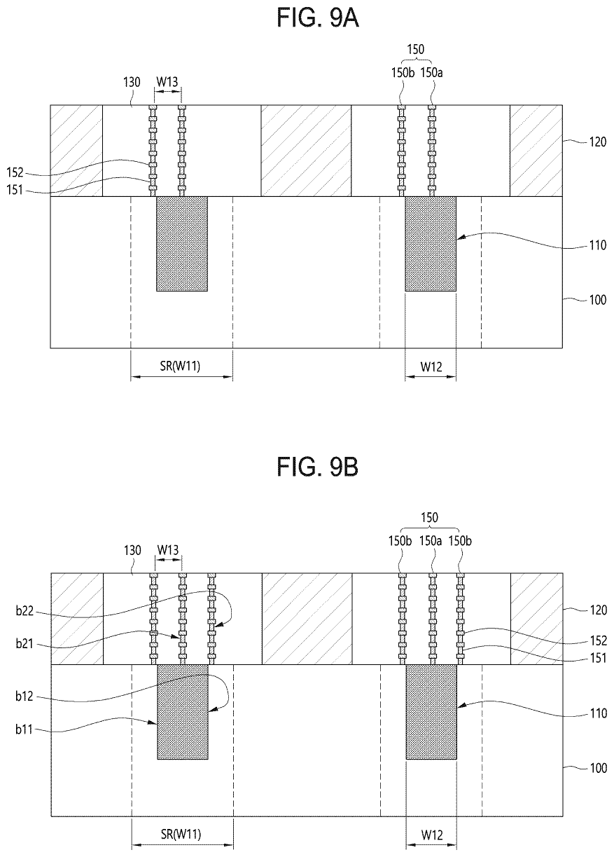

FIG. 3 is a flow chart of a method of manufacturing a semiconductor device in accordance with embodiments of the present disclosure. FIGS. 4A to 8A are plan views illustrating a method of manufacturing a semiconductor device in accordance with embodiments of the present disclosure and FIGS. 4B to 8B are cross-sectional views illustrating a method of manufacturing a semiconductor device in accordance with embodiments of the present disclosure. FIGS. 4B to 8B are cross-sectional views taken along a line a-a′ in FIGS. 4A to 8A. FIGS. 9A and 9B are cross-sectional views illustrating a method of manufacturing a semiconductor device in accordance with embodiments of the present disclosure.

Referring to FIGS. 3, 4A and 4B, the method may comprise forming a deep trench T in a bulk substrate 100 according to operation S10. The bulk substrate 100 may be prepared to include or provided with a plurality of semiconductor chip regions CH and a scribe lane region SR configured to separate the semiconductor chip regions CH. For example, the bulk substrate 100 may include a semiconductor substrate including Si, SiGe, Ge, and the like, but the embodiments are not limited thereto. In operation S10, the deep trench t may be formed in the bulk substrate 100 to have a width w12. The width w12 may be no more than about 0.1% to about 10%, particularly, about 1% to about 5% of a width w11 of the scribe lane region SR. For example, when the width w11 of the scribe lane region SR is about 40 μm, the width w12 of the deep trench t may be about 0.5 μm to about 1.5 μm. The deep trench t may have a first depth d1 measured from a surface of the bulk substrate 100. For example, the first depth d1 may correspond to a thickness of the bulk substrate 100 on which a back grinding process may be performed, i.e., a thickness of a thin substrate. The first depth d1 may be about 2 μm to about 4 μm. Because the first depth d1 of the deep trench t may be deeper than a depth of an isolation trench of the semiconductor chip region CH, damage and a stress may be applied to the bulk substrate 100 in forming the deep trench t.

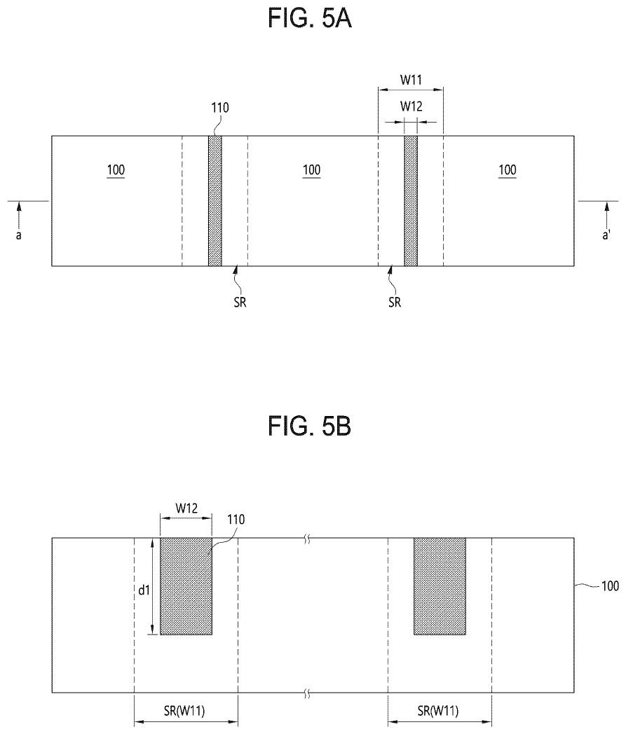

Referring to FIGS. 3, 5A and 5B, in operation S20, the method further comprises forming a gap-filling material within the deep trench t (refer to FIGS. 4A and 4B), thus forming a lower dicing inducer 110. Particularly, the gap-filling material may be formed on the bulk substrate 100 to fill up the deep trench t. The gap-filling material may include an insulation material, but the embodiments are not limited thereto. The gap-filling material may be planarized until the surface of the bulk substrate 100 may be exposed to form the lower dicing inducer 110 in the deep trench t. Cracks may be induced along a boundary of the lower dicing inducer 110 by a defect and a stress generated in forming the deep trench t, the heterojunction between the bulk substrate 100 and the lower dicing inducer 110 and a physical stress by the grinding of the gap-filling material.

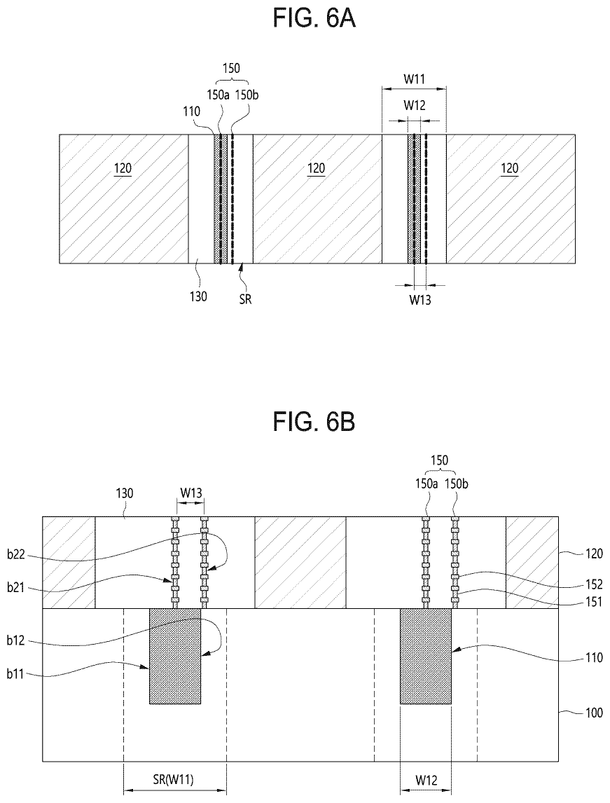

Referring to FIGS. 3, 6A and 6B, the method further comprises operation S30 which includes forming at least one upper dicing inducer 150 over the lower dicing inducer 110. Particularly, the upper dicing inducer 150 may be formed in the dummy layer 130 on the scribe lane region SR. For example, the upper dicing inducer 150 may have a contact chain's shape extended from a lower surface of the dummy layer 130 to an uppermost surface of the dummy layer 130. The contact chain of the upper dicing inducer 150 may include at least one vertical interconnection 151 and at least one horizontal interconnection 152 alternately arranged. As shown in the embodiment of FIG. 6B, the contact chain of the upper dicing inducer 150 includes a plurality of vertical and horizontal interconnections 151 and 152 alternately arranged.

In some embodiments, the upper dicing inducer 150 may include a first upper dicing inducer 150a and a second upper dicing inducer 150b. The first upper dicing inducer 150a may be positioned at a central portion of the lower dicing inducer 110. The second upper dicing inducer 150b may be positioned at an edge portion of the lower dicing inducer 110. A distance w13 between the first upper dicing inducer 150a and the second upper dicing inducer 150b may be about 3 μm to about 5 μm.

In some embodiments, the second upper dicing inducer 150b may be positioned adjacent to the second sidewall of b12 of the lower dicing inducer 110. Alternatively, as shown in FIG. 9A, the second upper dicing inducer 150b may be positioned adjacent to a first sidewall b11 of the lower dicing inducer 110. Further, as shown in FIG. 9B, the second upper dicing inducer 150b may be positioned adjacent to the first sidewall b11 and a second sidewall b12 of the lower dicing inducer 110.

On a planar view, at least one of the first upper dicing inducer 150a and the second upper dicing inducer 150b may have a pattern shape or a line shape. For example, the first upper dicing inducers 150a having the pattern shape may be arranged side by side at the central portion of the lower dicing inducer 110. The second upper dicing inducers 150b having the pattern shape may be arranged side by side at the edge portion of the lower dicing inducer 110. As a result, at least one of the first upper dicing inducers 150a and the second upper dicing inducers 150b may be continuously or discontinuously arranged along the scribe lane region SR.

A device layer 120 may be formed on the semiconductor chip region CH. The device layer 120 may include a plurality of circuit elements (not shown) having various functions and a plurality of insulation layers. For example, the plurality of circuit elements may include a plurality of transistors and a plurality of metal interconnections with contact chains. For example, the dummy layer 130 including the upper dicing inducer 150 may be formed simultaneously with processes for forming the device layer 120.

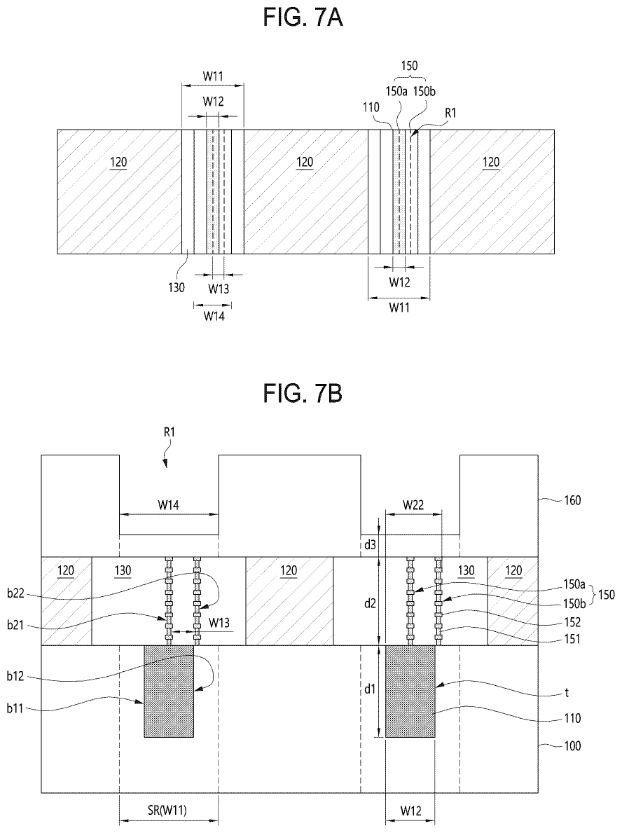

Referring to FIG. 3, the method may further include forming a recess according to operation S40. Referring to FIGS. 3, 7A and 7B, in operation S40, first a passivation layer 160 may be formed over the device layer 120 and the dummy layer 130. The passivation layer 160 may include an insulation layer having a predetermined thickness, for example, several to tens of micrometers(μm). Then, the passivation layer 160 may be etched to form recess R1 in the passivation layer 160. Portions of the passivation layer 160 overlapped with the lower dicing inducer 110 and the upper dicing inducer 150 may be exposed through the recess R1.

In some embodiments, a width w14 of the recess R1 may be greater than a distance w22 from an outermost boundary between the first sidewall b11 of the lower dicing inducer 110 and the first sidewall b21 of the upper dicing inducer 150 to an outermost boundary between the second sidewall b12 of the lower dicing inducer 110 and the second sidewall b22 of the upper dicing inducer 150. For example, as shown in FIG. 7B, the outermost boundary between the first sidewall b11 of the lower dicing inducer 110 and the first sidewall b21 of the upper dicing inducer 150 may correspond to the first sidewall b11 of the lower dicing inducer 110. The outermost boundary between the second sidewall b12 of the lower dicing inducer 110 and the second sidewall b22 of the upper dicing inducer 150 may correspond to the second sidewall b22 of the upper dicing inducer 150, particularly, the second upper dicing inducer 150b. A width w14 of the recess R1 may be narrower than the width w11 of the scribe lane region SR. The width w14 of the recess R1 may be wider than the width w12 of the lower dicing inducer 110. For example, the width w14 of the recess R1 may be about 0.5 μm to about 40 μm.

Because the passivation layer 160 is etched to form the recess R1 with a required depth, a great amount of stresses may be applied to the boundary of the recess R1 for a long etching time. However, in some embodiments, the recess R1 may be formed by etching a part of the passivation layer 160, not the whole passivation layer 160 which reduces the etching time. For example, after etching the passivation layer 160, the passivation layer 160 having a set thickness d3 may remain between the bottom surface of the recess R1 and the upper dicing inducer 150. The set thickness d3 may be about 25% to about 35% of a sum of a height of the lower dicing inducer 110, i.e., the depth d1 of the deep trench and a height d2 of the upper dicing inducer 150. The set thickness d3 may be designed to allow cracks generated by the etching process for forming the recess R1 and the back grinding process to promulgate and progress.

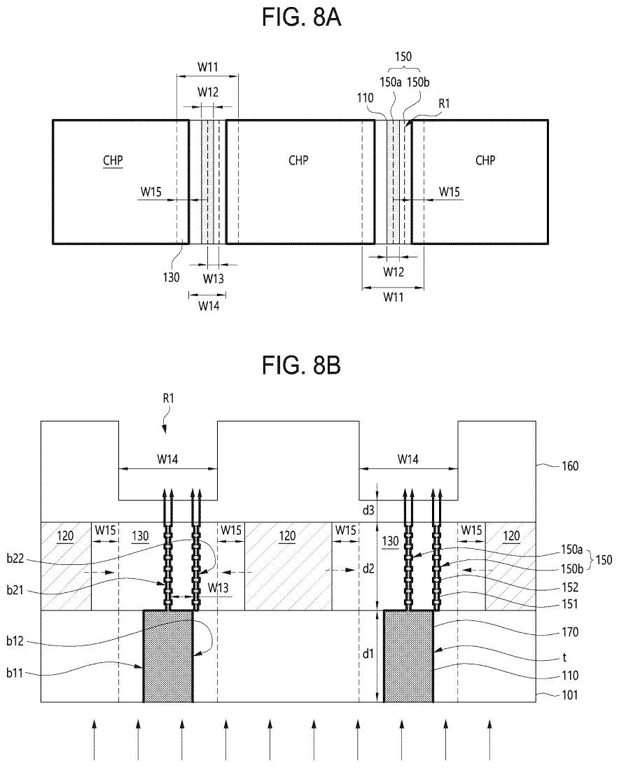

Referring to FIGS. 3, 8A and 8B, a backside of the bulk substrate 100 may be grinded to form a thin substrate 101, a process indicated by the arrows. For example, the backside of the bulk substrate 100 may be grinded until a bottom surface of the lower dicing inducer 110 may be exposed. A great amount of the stresses may be applied to the backside of the bulk substrate 100 during the back grinding process.

The stresses may be concentrated on a space between the thin substrate 101 and the sidewalls b11 and b12 of the lower dicing inducer 110 having the low bonding strength to induce the cracks 170 along a lower boundary between the thin substrate 101 and the sidewalls b11 and b12 of the lower dicing inducer 110.

Further, the cracks 170 may be upwardly moved along a boundary between the uppermost surface of the lower dicing inducer 110 and the dummy layer 130 and a boundary between the dummy layer and the upper dicing inducer 150. As mentioned above, since the bonding strength at the boundaries b11 and b12 is relatively weak due to the heterojunction of the lower dicing inducer 110 and the thin substrate 101, the stresses can penetrate into the boundaries and cause the cracks 170.

In some embodiments, when the upper dicing inducer 150 may include the first upper dicing inducer 150a in the central portion of the lower dicing inducer 110 and the second upper dicing inducer 150b in the edge portion of the lower dicing inducer 110, the cracks 170 may be progressed along the sidewalls b21 and b22 of the first and second upper dicing inducers 150a and 150b. For example, as the stresses are applied to an adjacent area where the bonding strength is relatively weakened due to the heterojunctions of the boundaries b21 and b22, the cracks 170 may be rapidly promulgated and progressed. Thus, although any boundary due to the heterojunction or any dicing inducer might not exist between the uppermost surface of the upper dicing inducer 150 and the bottom surface of the recess R1, the cracks 170 may be readily promulgated/generated by the spread of the stress.

As a result, in operation S50, the thin substrate 101 may be cut to singulate the chip CHP including the semiconductor chip region and the device layer 120 on the semiconductor chip region by the cracks vertically progressed in forming the recess R1 and the back grinding process.

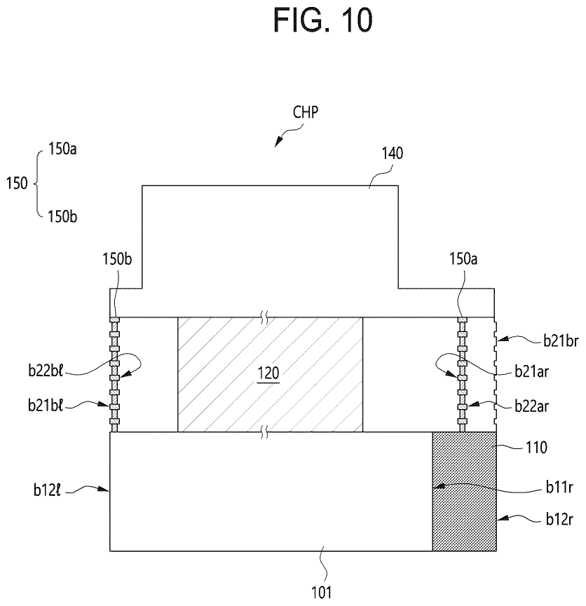

FIG. 10 is a cross-sectional view illustrating a semiconductor chip in accordance with some embodiments of the present disclosure.

Referring now to FIG. 10, one edge portion of a semiconductor chip CHP may be defined by cracks generated along the second sidewall b12l of a lower dicing inducer and first sidewall b21bl of the second upper dicing inducer 150b. The other edge portion of the semiconductor chip CHP may be defined by cracks generated along the second sidewall b12r of the lower dicing inducer 110 and first sidewall b21br of a second upper dicing inducer.

Therefore, the second upper dicing inducer 150b may remain on the one edge portion of the semiconductor chip CHP. The lower dicing inducer 110 and the first upper dicing inducer 150a may remain on the other edge portion of the semiconductor chip CHP.

The remaining lower and upper dicing inducers 110 and 150 may surround the semiconductor chip CHP to protect the device layer 120 in the semiconductor chip CHP. The remaining lower and upper dicing inducers 110 and 150 may be positioned outside a guard ring pattern to block particles and moistures.

A reference numeral b11r may indicate the first sidewall of the lower dicing inducer 110 positioned at the other edge portion of the semiconductor chip CHP. A reference numeral b22bl may indicate the second sidewall of the second upper dicing inducer 150b positioned at the one edge portion of the semiconductor chip CHP. A reference numeral b21ar may indicate the first sidewall of the first upper dicing inducer 150a positioned at the other edge portion of the semiconductor chip CHP. A reference numeral b22ar may indicate the second sidewall of the first upper dicing inducer 150a positioned at the other edge portion of the semiconductor chip CHP.

Further, the semiconductor chip CHP of some embodiments may be defined by cracks generated at various sidewalls.

According to some embodiments, the wafer may be cut to form the semiconductor chips by the back grinding process and the process for forming the recess R1 without the laser beam. Thus, it might not be required to set the scribe lane region considering a diffusion margin of the laser beam. As a result, the width of the scribe lane region may be decreased to the width of the recess considering the positions of the lower and upper dicing inducers. Therefore, the area of the semiconductor chip may be secured in the wafer by decreasing the width of the scribe lane region in the wafer. Further, a cost for manufacturing the semiconductor device may be reduced by omitting the laser beam.

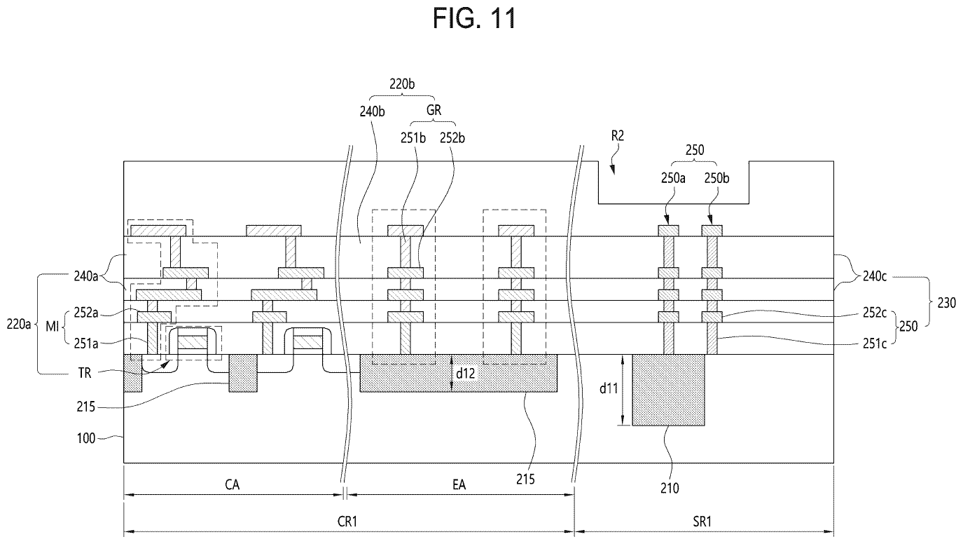

FIG. 11 is a cross-sectional view illustrating a method of manufacturing a semiconductor device in accordance with embodiments of the present disclosure.

Referring to FIG. 11, a bulk substrate 100 may be prepared. The bulk substrate 100 may include a semiconductor chip region CR1 and a scribe lane region SR1 adjacent to the semiconductor chip region CR1 in a horizontal direction. The semiconductor chip region CR1 may include a cell region CA and an edge region EA adjacent to each other in the horizontal direction. The edge region EA may be positioned between the cell region CA and the scribe lane region SR1. Various functional elements may be integrated in the cell region CA.

A lower dicing inducer 210 may be formed in the scribe lane region SR1. The lower dicing inducer 210 may have a first depth d11. For example, a top surface of the lower dicing inducer 210 may be coplanar with the top surface of the bulk substrate 100. A device isolation layer 215 may be formed in the semiconductor chip region CR1. The device isolation layer 215 may have a second depth d12 that is shallower than the first depth d11. The device isolation layer 215 may be formed by forming a shallow trench, which may have the second depth d12, and forming an insulating material in the shallow trench. The device isolation layer 215 may define an active region in the cell region CA. The device isolation layer 215 may be formed in the entire edge region EA. For example, the processes for forming the device isolation region 215 and the lower dicing inducer 210 may be simultaneously performed.

A first device layer 220a may be formed on the cell region CA. A second device layer 220b may be formed on the edge region EA. A dummy layer 230 may be formed on the scribe lane region SR1.

The first device layer 220a may include a plurality of transistors TR, a plurality of insulating interlayers 240a and a plurality of multi interconnections MI. The transistors TR may be integrated on the active region of the cell region CA.

The insulating interlayers 240a may be stacked on the active region with the transistors TR.

The multi interconnections MI may be connected between the transistors TR to transmit various signals between the transistors TR. The multi interconnections MI may be formed in the insulating interlayers 240a. The multi interconnections MI may include at least one vertical connection 251a and at least one horizontal connection 252a alternately arranged. For example, the vertical connection 251a may be formed through the at least one insulating interlayer 240a. The horizontal connection 252a may be positioned between the adjacent insulating interlayers 240a. The vertical connection 251a over the horizontal connection 252a may be electrically connected with the vertical connection 251a under the horizontal connection 252a via the horizontal connection 252a.

The second device layer 220b may include a plurality of insulating interlayers 240b and at least one guard ring GR.

The insulating interlayers 240b of the second device layer 220b may be extended from the insulating interlayers 240a of the first device layer 220a. That is, the insulating interlayers 240b of the second device layer 220b may have a configuration substantially the same as a configuration of the insulating interlayers 240a of the first device layer 220a.

The guard ring GR may be positioned in the insulating interlayers 240b. The guard ring GR may protect the first device layer 220a in the semiconductor chip. For example, the guard ring GR may include at least one vertical connection 251b and at least one horizontal connection 252b alternately stacked in a vertical direction. The vertical connection 251b may be formed through the at least one insulating interlayer 240b. The horizontal connection 252b may be positioned between the adjacent insulating interlayers 240b. For example, a first vertical connection 251b over a first horizontal connection 252b may be connected with a second vertical connection 251b via a second horizontal connection 252b and this pattern may be continued as may be needed. In the illustrated embodiment, the guard ring GR may include a plurality of the vertical connections 251b and a plurality of the horizontal connections 252b, and the horizontal connections 252b may have a same shape while the vertical connections 251b may have a same cross-section but different lengths.

The dummy layer 230 may include a plurality of insulating interlayers 240c stacked over the bulk substrate 100 and at least one upper dicing inducer 250, or as illustrated in the embodiment of FIG. 11 a plurality of upper dicing inducers 250a and 250b.

The insulating interlayers 240c of the dummy layer 230 may be extended from the insulating interlayers 240b of the second device layer 220b. That is, the insulating interlayers 240c, 240b and 240 of the dummy layer 230, the second device layer 220b and the first device layer 220a may have the same configuration.

The upper dicing inducer 250 may be formed in the insulating interlayers 240c over the lower dicing inducer 210 or in the insulating interlayers 240c around the lower dicing inducer 210. For example, the upper dicing inducer 250 may include a first upper dicing inducer 250a and at least one second upper dicing inducer 250b. The first upper dicing inducer 250a may be positioned at a central portion of the lower dicing inducer 10. The second upper dicing inducer 250b may be positioned at an edge portion of the lower dicing inducer 210. Each of the first and second upper dicing inducers 250a and 250b may include at least one vertical connection 251c and at least one horizontal connection 252c alternately arranged.

For example, the vertical connection 251c may be formed through the at least one insulating interlayer 240c. The horizontal connection 252c may be positioned between adjacent insulating interlayers 240c. The vertical and horizontal connections 251c and 252c may be connected in an alternating configuration. Hence, for example, a first vertical connection 251c over a first horizontal connection 252c may be connected with a second vertical connection 251c over the first horizontal connection 252c through the first horizontal connection 252c. As illustrated in FIG. 11, a lowermost vertical connection 251c may be in contact with the lower dicing inducer 210 and an uppermost horizontal connection 251c may be positioned on the top portion of the first and second upper dicing inducers 250a, and 250b, i.e., may be the top connection.

The upper dicing inducer 250 may be formed simultaneously with the multi interconnections MI of the first device layer 220a and the guard ring GR of the second device layer 220b. Thus, it may not be required to perform an additional process for forming the upper dicing inducer 250.

According to some embodiments, the dicing inducer may be formed to induce cracks from the scribe lane region to the dummy layer in the scribe lane region. The cracks may be vertically progressed in the wafer by a material difference between the dicing inducer and the substrate and between the dicing inducer and the dummy layer, and the stress applied in the back grinding process and the recess formation process without the laser.

Further, the dicing inducer may be formed simultaneously with the device isolation layer, the multi interconnection and the guard ring of the first and second device layers so that it might not be required to perform an additional process for forming the dicing inducer. Therefore, the wafer may be cut using the cracks generated within the dicing inducer without the laser or the blade. As a result, the width of the scribe lane region may be decreased to the width of the dicing inducer. The decreased width of the scribe lane region may be used for the width of the semiconductor chip to secure the area of the semiconductor chip.

The above described embodiments of the present disclosure are intended to illustrate and not to limit the embodiments. Various alternatives and equivalents are possible. The embodiments are not limited by the embodiments described herein. Nor are the embodiments limited to any specific type of semiconductor device. Additions, subtractions, or modifications which are apparent in view of the present disclosure and are intended to fall within the scope of the appended claims. Furthermore, the embodiments may be combined to form additional embodiments.

What is claimed is:

1. A method of manufacturing a semiconductor device, the method comprising:
providing a bulk substrate including a plurality of semiconductor chip regions and a scribe lane region positioned between the plurality of the semiconductor chip regions;
forming a lower dicing inducer having a first depth in the scribe lane region of the bulk substrate;
forming a dummy layer on the scribe lane region of the bulk substrate, the dummy layer including at least one upper dicing inducer;
forming a passivation layer over the dummy layer;
etching the passivation layer to form a recess in the passivation layer; and
grinding a backside of the bulk substrate to generate cracks along at least one of a boundary of the lower dicing inducer, a boundary of the upper dicing inducer, a boundary between the bulk substrate and the dummy layer, and a boundary of the recess, thereby singulating the plurality of the semiconductor chip regions by the cracks.

2. The method of claim 1, wherein forming the lower dicing inducer comprises:
etching the bulk substrate by the first depth to form a deep trench; and
filling the deep trench with an insulating material.

3. The method of claim 2, further comprising forming a device isolation layer in the plurality of the semiconductor regions of the bulk substrate, the device isolation layer having a second depth shallower than the first depth.

4. The method of claim 3, wherein forming the lower dicing inducer and forming the device isolation layer are simultaneously performed.

5. The method of claim 1, wherein forming the upper dicing inducer comprises:
forming a first upper dicing inducer at a central portion of the lower dicing inducer; and
forming at least one second upper dicing inducer at an edge portion of the lower dicing inducer.

6. The method of claim 5, wherein forming the dummy layer comprises:
forming a lower insulating interlayer on the bulk substrate;
forming a lower vertical connection in the lower insulating interlayer;
forming a horizontal connection on the lower insulating interlayer, wherein the horizontal connection is connected to the lower vertical connection;
forming an upper insulating interlayer on the lower insulating interlayer and the horizontal connection; and
forming an upper vertical connection on the upper insulating interlayer, wherein the upper vertical connection contacts the horizontal connection.

7. The method of claim 1, wherein each of the plurality of the semiconductor chip regions comprises a cell region and an edge region, and
further comprising:
forming a first device layer on the cell region, the first device layer including a multi interconnection; and
forming a second device layer on the edge region, the second device layer including at least one guard ring,
wherein forming the dummy layer is performed simultaneously with at least one of forming the first device layer and forming the second device layer.

8. The method of claim 1, wherein forming the recess comprises etching the passivation layer until an uppermost surface of the upper dicing inducer is exposed to form a passivation layer remainder having a set thickness.

9. The method of claim 8, wherein the set thickness of the passivation layer remainder is 25% to 35% of a sum of the first depth and a height of the upper dicing inducer.

10. The method of claim 1, wherein the recess is configured to expose the passivation layer overlapped with the lower dicing inducer and the upper dicing inducer.

11. The method of claim 10, wherein the recess has a width greater than a distance from an outermost boundary between a first sidewall of the lower dicing inducer and a first sidewall of the upper dicing inducer to an outermost boundary between the a second sidewall of the lower dicing inducer and a second sidewall of the upper dicing inducer.

12. The method of claim 10, wherein the recess has a width wider than a width of the lower dicing inducer and narrower than a width of the scribe lane region.

13. The method of claim 1, wherein the backside of the bulk substrate is grinded until a lower surface of the lower dicing inducer is exposed.

14. The method of claim 1, wherein the lower dicing inducer has a width narrower than a width of the scribe lane region.
